(19) United States
(12) Patent Application Publication
(10) Pub. No.: US 2011/0240116 A1
(43) Pub. Date: Oct. 6, 2011

(54) PHOTOELECTRIC CONVERSION DEVICE AND PROCESS FOR PRODUCTION THEREOF

(75) Inventor: Masahiro Morooka, Kanagawa (JP)

(73) Assignee: Sony Corporation, Tokyo (JP)

(21) Appl. No.: 13/053,863

(22) Filed: Mar. 22, 2011

(30) Foreign Application Priority Data
Mar. 31, 2010 (JP) 2010-080221

(51) Int. Cl. H01L 31/0224; H01L 31/0376; H01L 51/44; H01L 31/18

(52) U.S. Cl. 136/256; 438/96; 257/E31.047

(57) ABSTRACT

Disclosed herein is a process for producing a photoelectric conversion device, including the steps of: coating the surface of a conductive substrate with a porous catalyst layer; coating the surface of the conductive substrate with a porous insulating layer in such a way as to cover the porous catalyst layer; coating the surface of the porous insulating layer with a current collecting layer; coating the surface of the porous insulating layer with a porous metal oxide semiconductor layer in such a way as to cover the current collecting layer; allowing the porous metal oxide semiconductor layer to support a dye; impregnating the porous metal oxide semiconductor layer, the porous insulating layer, and the porous catalyst layer with an electrolyte solution; and forming a transparent sealing layer in such a way as to cover at least the porous insulating layer and the porous metal oxide semiconductor layer.

### BACKGROUND OF THE INVENTION

1. Field of the Invention

The present invention relates to a photoelectric conversion device which achieves a light weight, good flexibility, small thickness, and high conversion efficiency, and also to a process for production thereof.

2. Description of the Related Art

The recent increasing concern about environmental protection has attached more importance to solar power generation by dye-sensitized solar cells (DSSC). The DSSC is composed of a transparent substrate and transparent conductor layer and oxide semiconductor layer formed thereon. The oxide semiconductor layer supports a sensitizing dye and functions as a working electrode (or photoelectrode or window electrode). The working electrode is coupled with a counter electrode, with an oxidation reduction electrolyte layer interposed between them. The constructed dye-sensitized solar cell works as a battery in such a way that the dye helps sunlight to excite electrons and excited electrons flow into the oxide semiconductor layer and the transparent conductive film and eventually flow into the counter electrode through the external circuit including loads.

The dye-sensitized solar cell is economically superior to silicon-based ones because it is less restricted by its raw materials, it does not need any vacuum system, and it is suitable for flow production by printing (which is advantageous costwise). Efforts are being directed to developments of flexible dye-sensitized solar cells which employ a plastics sheet as the supporting substrate. (See Japanese Patent Laid-open No. 2009-146625 (Paragraphs 0010, 0037, and 0042, and FIGS. 1 to 3) referred to as Patent Document 1 hereinafter.)

The dye-sensitized solar cell is usually constructed such that a substrate having a working electrode formed thereon and another substrate having a counter electrode formed thereon face each other and their gap is filled with an electrolyte layer, and the entire assembly is sealed. Attempts are being made to coat a single substrate with various layers necessary for the dye-sensitized solar cell. (See WO2007/026927 (Paragraphs 0321-0339 and FIGS. 4 and 5) referred to as Patent Document 2 hereinafter.)

### SUMMARY OF THE INVENTION

Existing processes for production of dye-sensitized solar cells need a baking step to form the porous metal oxide semiconductor layer or the dye-sensitized semiconductor layer. Baking has to be carried out at a temperature below about 150° C. because the plastics substrate is limited in heat resistant temperature (or glass transition point). Baking at such a low temperature gives rise to a porous metal oxide semiconductor layer which is low in electron conductivity owing to poor crystallinity and loose particle binding. Thus the dye-sensitized solar cell that employs a plastics substrate is inferior in generation efficiency to the one that employs a glass substrate.

Patent Document 1 discloses a dye-sensitized solar cell which employs as the supporting substrate a thin glass substrate having a thickness of 0.01 to 0.2 mm. In addition, the thin glass substrate is combined with a protective film bonded thereto for protection from breakage. This structure is undesirable for reduction in weight and thickness.

Patent Document 2 also discloses a dye-sensitized solar cell but it does not pay close attention to formation of the current collecting electrode that prevents the conversion efficiency from decreasing due to resistance loss by the transparent conductive layer.

The present invention was completed to solve the above-mentioned problems. Thus, it is an object of the present invention to provide a photoelectric conversion device and a process for production thereof, said device being light in weight, thin, and flexible and having an improved conversion efficiency.

According to an embodiment of the present invention, there is provided a process for producing a photoelectric conversion device, including:

a first step of coating a surface of a conductive substrate with a porous catalyst layer;

a second step of coating the surface of the conductive substrate with a porous insulating layer in such a way as to cover the porous catalyst layer;

a third step of coating the surface of the porous insulating layer with a current collecting layer;

a fourth step of coating the surface of the porous insulating layer with a porous metal oxide semiconductor layer in such a way as to cover the current collecting layer;

a fifth step of allowing the porous metal oxide semiconductor layer to support a dye;

a sixth step of impregnating the porous metal oxide semiconductor layer, the porous insulating layer, and the porous catalyst layer with an electrolyte solution; and

a seventh step of forming a transparent sealing layer in such a way as to cover at least the porous insulating layer and the porous metal oxide semiconductor layer.

According to another embodiment of the present invention, there is provided a photoelectric conversion device including:

a porous catalyst layer which is formed on a surface of a conductive substrate;

a porous insulating layer which is formed on the surface of the conductive substrate in such a way as to cover the porous catalyst layer;

a current collecting layer which is formed on the surface of the porous insulating layer;

a porous metal oxide semiconductor layer which is formed on the surface of the porous insulating layer in such a way as to cover the current collecting layer; and

a transparent sealing layer which is formed on the surface of the conductive substrate in such a way as to cover at least the porous insulating layer and the porous metal oxide semiconductor layer.

The porous metal oxide semiconductor layer supports a dye and the porous metal oxide semiconductor layer, the porous insulating layer, and the porous catalyst layer contain an electrolyte solution.

According to further embodiment of the present invention, there is provided a process for producing a photoelectric conversion device, including:

a first step of coating a surface of a conductive substrate with a porous catalyst layer;

a second step of coating the surface of the conductive substrate with a porous insulating layer in such a way as to cover the porous catalyst layer;

a third step of coating the surface of the porous insulating layer with a porous metal oxide semiconductor layer;

a fourth step of forming a current collecting layer in such a way that it is at least partly embedded in the porous metal oxide semiconductor layer;

a fifth step of forming a transparent electrode layer in such a way that it comes into contact with the porous metal oxide semiconductor layer and the current collecting layer;

a sixth step of allowing the porous metal oxide semiconductor layer to support a dye;

a seventh step of impregnating the porous metal oxide semiconductor layer, the porous insulating layer, and the porous catalyst layer with an electrolyte solution; and

an eighth step of forming a transparent sealing layer in such a way as to cover at least the porous insulating layer, the porous metal oxide semiconductor layer, and the transparent electrode layer.

According to still further embodiment of the present invention, there is provided a photoelectric conversion device including:

a porous catalyst layer which is formed on a surface of a conductive substrate;

a porous insulating layer which is formed on the surface of the conductive substrate in such a way as to cover the porous catalyst layer;

a porous metal oxide semiconductor layer which is formed on the surface of the porous insulating layer;

a current collecting layer which is formed in such a way that it is at least partly embedded in the porous metal oxide semiconductor layer;

a transparent electrode layer which is formed in such a way that it comes into contact with the porous metal oxide semiconductor layer and the current collecting layer; and

a transparent sealing layer which is so formed as to cover at least the porous insulating layer, the porous metal oxide semiconductor layer, and the transparent electrode layer.

The porous metal oxide semiconductor layer supports a dye and the porous metal oxide semiconductor layer, the porous insulating layer, and the porous catalyst layer contain an electrolyte solution.

According to an embodiment of the present invention, there is provided a process for producing a photoelectric conversion device, including:

a first step of coating a surface of a conductive substrate with a porous catalyst layer;

a second step of coating the surface of the conductive substrate with a porous insulating layer in such a way as to cover the porous catalyst layer;

a third step of coating the surface of the porous insulating layer with a porous metal oxide semiconductor layer;

a fourth step of forming a transparent electrode layer on the surface of the porous metal oxide semiconductor layer;

a fifth step of forming a current collecting layer which is formed on the surface of the transparent electrode layer;

a sixth step of allowing the porous metal oxide semiconductor layer to support a dye;

a seventh step of impregnating the porous metal oxide semiconductor layer, the porous insulating layer, and the porous catalyst layer with an electrolyte solution; and

an eighth step of forming a transparent sealing layer in such a way as to cover at least the porous insulating layer, the porous metal oxide semiconductor layer, and the transparent electrode layer.

According to another embodiment of the present invention, there is provided a photoelectric conversion device including:

a porous catalyst layer which is formed on a surface of a conductive substrate;

a porous insulating layer which is formed on the surface of the conductive substrate in such a way as to cover the porous catalyst layer;

a porous metal oxide semiconductor layer which is formed on the surface of the porous insulating layer;

a transparent electrode layer which is formed on the surface of the porous metal oxide semiconductor layer;

a current collecting layer which is formed on the surface of the transparent electrode layer; and

a transparent sealing layer which is so formed as to cover at least the porous insulating layer, the porous metal oxide semiconductor layer, and the transparent electrode layer.

The porous metal oxide semiconductor layer supports a dye and the porous metal oxide semiconductor layer, the porous insulating layer, and the porous catalyst layer contain an electrolyte solution.

According to the present invention, a photoelectric conversion device uses a metal sheet in place of a glass substrate as a conductive substrate, which is light in weight, thin, and flexible, and has an improved conversion efficiency.

### BRIEF DESCRIPTION OF THE DRAWINGS

FIGS. 1A to 1E are diagrams illustrating the steps for production of the dye-sensitized solar cell element pertaining to an embodiment of the present invention;

FIGS. 2A to 2F are diagrams illustrating the steps for production of the dye-sensitized solar cell element pertaining to another embodiment of the present invention;

FIGS. 3A to 3F are diagrams illustrating the steps for production of the dye-sensitized solar cell element pertaining to another embodiment of the present invention;

FIG. 4 is a sectional view showing the dye-sensitized solar cells in integrated form pertaining to one embodiment of the present invention; and

FIGS. 5A and 5B are diagrams illustrating the steps for production of the dye-sensitized solar cell by the roll-to-roll process pertaining to an embodiment of the present invention.

### DETAILED DESCRIPTION OF THE PREFERRED EMBODIMENTS

In the process for production of the photoelectric conversion device of the first structure, the sixth step may be accomplished by a substep of making an opening that penetrates said conductive substrate, a substep of injecting said electrolyte solution through said opening, thereby impregnating said porous metal oxide semiconductor layer, said porous insulating layer, and said porous catalyst layer with said electrolyte solution, and a substep of sealing said opening. The advantage of the foregoing process is that the photoelectric conversion device, which employs a metal sheet as the conductive substrate in place of a glass substrate, can be easily sealed by laser-welding said opening formed on the metal sheet without the entire device increasing in thickness.

In the process for production of the photoelectric conversion device of the second structure, the sixth step may be accomplished by a substep of making an opening that penetrates said conductive substrate, a substep of injecting said electrolyte solution through said opening, thereby impregnating said porous metal oxide semiconductor layer, said porous insulating layer, and said porous catalyst layer with said electrolyte solution, and a substep of sealing said opening. The advantage of the foregoing process is that the photoelectric conversion device, which employs a metal sheet as the conductive substrate in place of a glass substrate, can be easily sealed by laser-welding said opening formed on the metal sheet without the entire device increasing in thickness.

In the process for production of the photoelectric conversion device of the third structure, the seventh step may be accomplished by a substep of making an opening that penetrates said conductive substrate, a substep of injecting said electrolyte solution through said opening, thereby impregnating said porous metal oxide semiconductor layer, said porous insulating layer, and said porous catalyst layer with said electrolyte solution, and a substep of sealing said opening. The advantage of the foregoing process is that the photoelectric conversion device, which employs a metal sheet as the conductive substrate in place of a glass substrate, can be easily sealed by laser-welding said opening formed on the metal sheet without the entire device increasing in thickness.

The present invention will be described below in more detail with reference to the accompanying drawings which show the dye-sensitized solar cell element as the photoelectric conversion device pertaining to the embodiments thereof. The present invention is not restricted by the embodiments given below so long as it produces the above-mentioned effects. Incidentally, the accompanying drawings are intended to illustrate the structure for easy understanding and hence they are not exact in scale.

### First Embodiment

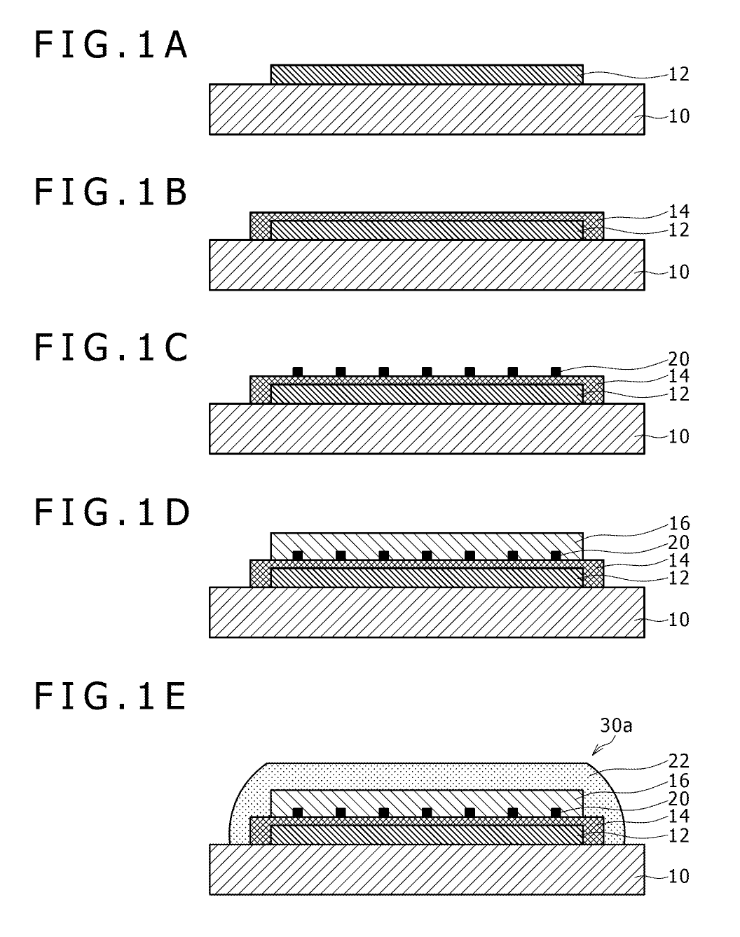

FIGS. 1A to 1E are diagrams illustrating the steps for production of the dye-sensitized solar cell element pertaining to the first embodiment of the present invention.

As shown in FIG. 1E, the dye-sensitized solar cell element 30a is composed of a substrate and functional layers sequentially formed thereon one over another. The substrate is the conductive sheet 10 of metal, such as Ti, in place of the glass substrate as the counter electrode. The functional layers include the porous carbon layer 12, the porous insulating layer 14, the current collecting grid 20, the porous metal oxide semiconductor layer 16, and the transparent sealing layer 22. The porous metal oxide semiconductor layer 16 contains a dye supported therein. The porous metal oxide semiconductor layer 16, the porous insulating layer 14, and the porous carbon layer 12 are impregnated with an electrolyte solution.

The porous carbon layer 12 is a catalyst layer. The porous insulating layer 14 is formed on the conductive sheet 10 in such a way as to cover the porous carbon layer 12. The current collecting grid 20 is formed on the porous insulating layer 14.

As shown in FIGS. 1A to 1E, the dye-sensitized solar cell element 30a is produced in the following way.

The first step shown in FIG. 1A starts with coating a conductive substrate, which is the conductive sheet 10 of metal such as Ti, with the porous carbon layer 12 which functions as a catalyst layer.

The second step shown in FIG. 1B is to cover the conductive sheet 10 with the porous insulating layer 14 over the porous carbon layer 12.

The third step shown in FIG. 1C is to cover the porous insulating layer 14 with a current collecting layer or the current collecting grid 20.

The fourth step shown in FIG. 1D is to coat the porous insulating layer 14 with the porous metal oxide semiconductor layer 16 by the coating method, with the current collecting grid 20 interposed between them, which is formed by application with a paste of titanium dioxide (anatase), followed by drying and baking at 400° C. to 500° C.

The fifth step shown in FIG. 1E is to treat the porous metal oxide semiconductor layer 16 with TiCl₄ for improvement in necking among particles of the metal oxide semiconductor, improvement in electron transfer, and improvement in photoelectric conversion efficiency. This step is accomplished by impregnating the porous metal oxide semiconductor layer 16 with a solution of TiCl₄, followed by rinsing with water and baking at 400° C. to 500° C.

The sixth step shown in FIG. 1E is to impregnate the porous metal oxide semiconductor layer 16 with a dye-containing solution and then with an electrolyte solution. This step causes the porous metal oxide semiconductor layer 16 to support the dye and also causes the porous metal oxide semiconductor layer 16 as well as the porous insulating layer 14 and the porous carbon layer 12 to be impregnated with the electrolyte solution.

The foregoing sixth step may be carried in an alternative way as follows. After the porous metal oxide semiconductor layer 16 has been impregnated with a dye-containing solution, the conductive sheet 10 is pierced through openings and the electrolyte solution is injected through these openings into the porous metal oxide semiconductor layer 16, the porous insulating layer 14, and the porous carbon layer 12. Finally, the openings are sealed.

The seventh step shown in FIG. 1E is to form the transparent sealing layer 22 that covers at least the porous metal oxide semiconductor layer 16 and the porous insulating layer 14.

As mentioned above, the dye-sensitized solar cell element 30a is produced by the steps of coating a metal sheet sequentially with a porous catalyst layer, a porous insulating layer, a current collecting grid, and a porous titanium dioxide layer, allowing the porous titanium dioxide layer to support a dye, impregnating the porous titanium dioxide layer, the porous insulating layer, and the porous catalyst layer with an electrolyte solution, and finally covering the assembly with a transparent plastic resin. The metal sheet functions as a conductive substrate in place of a glass substrate.

Thus the dye-sensitized solar cell element 30a is composed of a working electrode, a counter electrode, and an electrolyte solution as explained below. The working electrode (or the photoelectrode or window electrode) includes the porous metal oxide semiconductor layer 16 and a sensitizing dye supported by particles constituting the porous metal oxide semiconductor layer 16. The counter electrode (opposite to the working electrode) includes the conductive sheet 10 and the porous carbon layer 12. The electrolyte solution which contains a redox electrolyte is held in the porous metal oxide semiconductor layer 16, the porous insulating layer 14, and the porous carbon layer 12.

The dye-sensitized solar cell element 30a has a metal sheet as the conductive substrate in place of a glass substrate. Therefore, it is light in weight, thin, and flexible and yet withstands the high-temperature process which leads to improved conversion efficiency and high performance.

The conductive sheet 10 of Ti shown in FIGS. 1A to 1E may be replaced by any metal sheet or foil of Ni, Au, or Pt. The conductive sheet 10 may also be replaced by a plastic resin sheet or film laminated with a transparent conductive film of ITO (Indium Tin Oxide) or FTO (Fluorine-doped Tin Oxide) or by a plastic sheet or film having a metal film of Ti, Ni, Au, or Pt formed thereon.

The porous carbon layer 12 (as the catalyst layer) shown in FIGS. 1A to 1E may be replaced by any catalytic material, such as Pt, Rh, Ru, Pd, Cd, Os, and Ir, which is conductive and capable of promoting and executing at sufficient speed the redox reaction for I₃⁻ ions (redox ions of oxide type) in the electrolyte. It may also be replaced by any conductive polymer, such as polypyrrole, polythiophene, polyaniline, polyfuran, polyacetylene, polyphenylene, polyazulene, polyfluorene, and derivatives thereof, and poly(3,4-ethylenedioxythiophene)/polystyrenesulfonic acid (PEDOT/PSS).

Incidentally, the catalyst layer may be omitted in the case where the conductive sheet 10 is a metal sheet or foil of Pt, Rh, or Ru.

The porous insulating film 14 shown in FIGS. 1B to 1E is intended for electrical insulation between the porous carbon layer 12 (as a catalyst layer) and both the current collecting grid 20 and the porous metal oxide semiconductor layer 16. It is formed from a porous insulating material, so that it may contain an electrolyte solution. It should be as thin as possible so that the distance for oxidation reduction reaction or hole transfer is reduced. This leads to a high conversion efficiency.

The porous insulating layer 14 may be formed from any ceramic material such as oxide ceramics, nitride ceramics, and carbide ceramics, which include CoO, NiO, FeO, Al₂O₃, SiO₂, MgO, ZrO₂, MoO₂, Cr₂O₃, SrCu₂O₂, WO₃, In₂O₃, Bi₂O₃, CeO₂, Nb₂O₅, Y₂O₃, silicon nitride, sialon, titanium nitride, aluminum nitride, silicon carbide, titanium carbide and aluminum carbide.

The porous insulating layer 14 may be formed by any one of various methods such as screen printing, doctor blading, ink jet printing, drop casting, spin coating, and electrostatic spraying.

The current collecting grid 20 shown in FIGS. 1C to 1E is formed from any material having a low electrical resistance and a high resistance to corrosion by components contained in the electrolyte solution. Such materials include Ti, Cr, Ni, Nb, Mo, Ru, Rh, Ta, W, Ir, Pt, and hastelloy (trademark of Haynes International, Inc.). Hastelloy includes alloys composed mainly of Ni, which are denoted by Hastelloy B, Hastelloy C X, Hastelloy G, etc. depending on their constituents such as Cr, Fe, Co, Cu, Mo, and W.

The current collecting grid 20 may be formed by any of CVD (Chemical Vapor Deposition) method, sputtering, electroless plating, and printing, which are commonly used to form electrodes. Alternatively, it may be formed by placing a metal mesh on the porous insulating layer 14. The current collecting grid 20 may be formed in any shape, such as lattice, net, stripe, and comb.

The porous metal oxide semiconductor layer 16 shown in FIGS. 1D and 1E may be formed from any other materials than titanium oxide (TiO₂), which are commonly used for photoelectric conversion. They include, for example, zinc oxide (ZnO), tungsten oxide (WO₃), niobium oxide (Nb₂O₅), strontium titanate (SrTiO₃), tin oxide (SnO₂), indium oxide (In₃O₃), zirconium oxide (ZrO₂), thallium oxide (Ta₂O₅), lanthanum oxide (La₂O₃), yttrium oxide (Y₂O₃), holmium oxide (Ho₂O₃), bismuth oxide (Bi₂O), cerium oxide (CeO₂), and alumina (Al₂O₃), which are semiconductor compounds.

The porous metal oxide semiconductor layer 16 shown in FIGS. 1D and 1E contains a dye which functions as a photosensitizing agent adsorbed thereto. This dye may be selected from various known organic dyes and metal complex dyes which have an absorption band in the visible region and/or infrared region.

Examples of the organic dyes include azo dyes, quinone dyes, quinoneimine dyes, quinacridone dyes, squarylium dyes, cyanine dyes, merocyanine dyes, triphenylmethane dyes, xanthene dyes, porphyrin dyes, phthalocyanine dyes, perylene dyes, indigo dyes, and naphthalocyanine dyes.

Examples of the metal complex dyes include ruthenium metal complex dyes such as ruthenium bipyridine metal complex dyes, ruthenium terpyridine metal complex dyes, and ruthenium quaterpyridine metal complex dyes.

For the foregoing dyes to be firmly adsorbed to the porous metal oxide semiconductor layer, they should preferably have in their dye molecules any of such interlocking groups as carboxyl group, alkoxyl group, hydroxyl group, hydroxyalkyl group, sulfonic group, ester group, mercapto group, and phosphonyl group. Of these interlocking groups, the carboxyl group (COOH) is desirable. The interlocking group usually permits the dyes to be adsorbed and fixed to the surface of the semiconductor and provides the electrical coupling that facilitates electron movement between the excited dye and the conduction band of the porous metal oxide semiconductor layer.

The electrolyte solution shown in FIG. 1E may be any electrolyte solution which contains cations such as lithium ions and anions such as chlorine ions. The electrolyte solution should preferably contain an oxidation-reduction pair that reversibly takes on the oxidized structure and the reduced structure. Examples of the oxidation-reduction pair include iodine-iodine compound, bromine-bromine compound, and quinone-hydroquinone.

The transparent sealing layer 22 shown in FIG. 1E may be formed from any plastics resin having transparency and high weather resistance and also having an ability to protect the laminated layers. Examples of such plastics resin include fluororesin, polyester resin, polycarbonate resin, acrylic resin, polyethylene terephthalate (PET) resin, polyvinyl chloride resin, ethylene-vinyl acetate copolymer (EVA) resin, polyvinyl butyral (PVB) resin, epoxy resin, polyamideimide resin, silicone resin, and urethane resin.

The individual layers constituting the dye-sensitized solar cell element 30a may have a thickness specified below.

The conductive sheet 10 may have any thickness without specific restrictions. It may have any thickness that conforms to the cell structure. Its adequate thickness desirable for mechanical strength is no smaller than 0.001 mm and no larger than 1 mm, preferably no smaller than 0.005 mm and no larger than 0.5 mm.

The porous carbon layer 12 should preferably be sufficiently thick so that it has a large surface area. However, with an excessively large thickness, it will cause the sealing layer to increase in thickness. Its adequate thickness is no smaller than 1 μm and no larger than 200 μm, preferably no smaller than 5 μm and no larger than 100 μm.

The porous insulating layer 14 is not restricted in thickness. It may have any thickness that conforms to the structure of the cell structure. It should have a thickness no smaller than 1 μm and no larger than 100 μm, preferably no smaller than 3 μm and no larger than 20 μm, which is necessary to prevent short and to ensure an adequate diffusion distance for electrolyte.

The current collecting grid 20 is not restricted in thickness. Its adequate thickness is no smaller than 0.1 μm and no larger than 100 μm, preferably no smaller than 1 μm and no larger than 50 μm.

The porous metal oxide semiconductor layer 16 varies in adequate thickness depending on the dye employed. Its adequate thickness is no smaller than 1 μm and no larger than 100 μm, preferably no smaller than 5 μm and no larger than 50 μm.

The transparent sealing layer 22 is not restricted in thickness. Its adequate thickness is no smaller than 1 μm and no larger than 1 mm, preferably no smaller than 10 μm and no larger than 100 μm.

### Second Embodiment

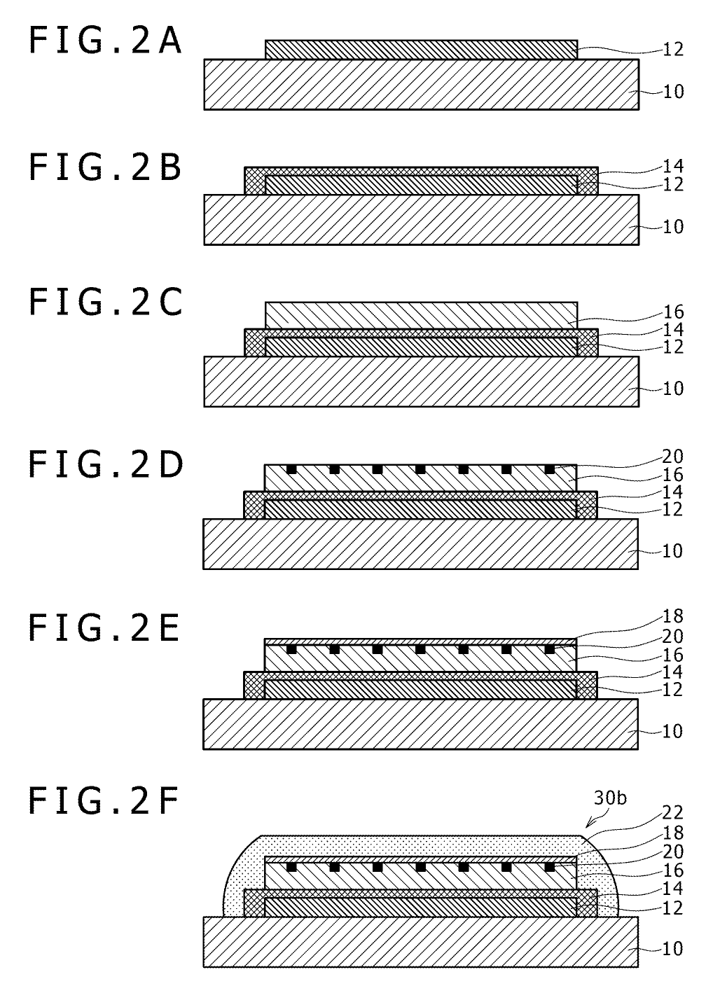

FIGS. 2A to 2F are diagrams illustrating the steps for production of the dye-sensitized solar cell element pertaining to the second embodiment of the present invention.

As shown in FIG. 2F, the dye-sensitized solar cell element 30b is composed of a substrate and functional layers sequentially formed thereon one over another, as in the case of the dye-sensitized solar cell element 30a shown in FIG. 1E. The substrate is the conductive sheet 10 of metal, such as Ti, in place of the glass substrate as the counter electrode. The functional layers include the porous carbon layer 12, the porous insulating layer 14, the porous metal oxide semiconductor layer 16, the current collecting grid 20, the transparent electrode layer 18, and the transparent sealing layer 22. The porous metal oxide semiconductor layer 16 contains a dye supported therein. The porous metal oxide semiconductor layer 16, the porous insulating layer 14 and the porous carbon layer 12 are impregnated with an electrolyte solution.

The porous carbon layer 12 is a catalyst layer. The porous insulating layer 14 is formed on the conductive sheet 10 in such a way as to cover the porous carbon layer 12, and the porous insulating layer 14 is covered with the porous metal oxide semiconductor layer 16 formed thereon. The porous metal oxide semiconductor layer 16 is covered with the current collecting grid 20 which is at least partly embedded therein.

As shown in FIGS. 2A to 2F, the dye-sensitized solar cell element 30b is produced in the following way.

The first step shown in FIG. 2A starts with coating a conductive substrate, which is the conductive sheet 10 of metal such as Ti, with the porous carbon layer 12 which functions as a catalyst layer, in the same way as shown in FIG. 1A.

The second step shown in FIG. 2B is to cover the conductive sheet 10 with the porous insulating layer 14 over the porous carbon layer 12, in the same way as shown in FIG. 1B.

The third step shown in FIG. 2C is to coat the porous insulating layer 14 with titanium dioxide (anatase) in paste form to form the porous metal oxide semiconductor layer 16 thereon, in the same way as shown in FIG. 1D.

The fourth step shown in FIG. 2D is to form the current collecting grid 20 on the porous metal oxide semiconductor layer 16 in such a way that the former is at least partly embedded in the latter. The current collecting grid 20 may be formed in the grooves, which have been previously formed in the porous metal oxide semiconductor layer 16, by any of CVD method, sputtering, electroless plating, and printing, which are generally employed to form electrodes, as mentioned above with reference to FIGS. 1A to 1E. Alternatively, the current collecting grid 20 may be formed by placing a metal mesh in the above-mentioned grooves such that it comes into contact with the porous metal oxide semiconductor layer 16. The above-mentioned grooves are not specifically restricted in its layout pattern; they may be arranged in a lattice pattern, net pattern, stripy pattern, or comb pattern.

The fifth step shown in FIG. 2E is to treat the porous metal oxide semiconductor layer 16 with TiCl₄, in the same way as shown in FIG. 1E, for improvement in necking among particles of the metal oxide semiconductor, improvement in electron transfer, and improvement in photoelectric conversion efficiency. This step may precede the step of forming the current collecting grid 20 shown in FIG. 2D.

The sixth step shown in FIG. 2E is to form the transparent electrode layer 18 which is in contact with the current collecting grid 20 and the porous metal oxide semiconductor layer 16. The transparent electrode layer 18 is formed from a conductive metal oxide selected from indium oxide, tin-doped indium oxide (ITO), zinc-doped indium oxide (IZO), tin oxide, antimony-doped tin oxide (ATO), fluorine-doped tin oxide (FTO), zinc oxide, and aluminum-doped zinc oxide (AZO).

The seventh step shown in FIG. 2F is to impregnate the porous metal oxide semiconductor layer 16 with a dye-containing solution, so that the porous metal oxide semiconductor layer 16 supports the dye. This step is followed by impregnating the porous metal oxide semiconductor layer 16, the porous insulating layer 14, and the porous carbon layer 12 with an electrolyte solution.

If the transparent electrode layer 18 is a porous one, it can be impregnated with a dye-containing solution so that the porous metal oxide semiconductor layer 16 supports the dye. The transparent electrode layer 18 can also be impregnated with an electrolyte solution so that the porous metal oxide semiconductor layer 16, the porous insulating layer 14, and the porous carbon layer 12 are impregnated with the electrolyte solution.

If the transparent electrode layer 18 is not a porous one, the porous metal oxide semiconductor layer 16 may be impregnated with a dye-containing solution through a plurality of small through-holes made in the transparent electrode layer 18, so that the porous metal oxide semiconductor layer 16 supports the dye. These small through-holes may also be used to impregnate the porous metal oxide semiconductor layer 16, the porous insulating layer 14, and the porous carbon layer 12 with the electrolyte solution.

Incidentally, the seventh step may be carried out differently than mentioned above by allowing the porous metal oxide semiconductor layer 16 to support the dye, forming the through-holes in the conductive sheet 10, injecting the electrolyte solution through these through-holes, thereby allowing the electrolyte solution to infiltrate into the porous metal oxide semiconductor layer 16, the porous insulating layer 14, and the porous carbon layer 12, and finally sealing the through-holes.

The eighth step shown in FIG. 2F is to form the transparent sealing layer 22 which covers at least the transparent electrode layer 18, the porous metal oxide semiconductor layer 16, and the porous insulating layer 14.

As mentioned above, the dye-sensitized solar cell element 30b is produced in the same way as shown in FIGS. 1A to 1E, by the steps of coating a metal sheet sequentially with a porous catalyst layer, a porous insulating layer, a porous titanium dioxide layer, a current collecting grid, and a transparent electrode layer, allowing the porous titanium dioxide layer to support a dye, impregnating the porous titanium dioxide layer, the porous insulating layer, and the porous catalyst layer with an electrolyte solution, and finally covering the assembly with a transparent plastic resin. The metal sheet functions as a conductive substrate in place of a glass substrate.

Thus the dye-sensitized solar cell element 30b is composed of a working electrode, a counter electrode, and an electrolyte solution as explained below. The working electrode (or the photoelectrode or window electrode) includes the porous metal oxide semiconductor layer 16 and a sensitizing dye supported by particles constituting the porous metal oxide semiconductor layer 16. The counter electrode opposite to the working electrode includes the conductive sheet 10 and the porous carbon layer 12. The electrolyte solution which contains a redox electrolyte is held in the porous metal oxide semiconductor layer 16, the porous insulating layer 14, and the porous carbon layer 12.

The dye-sensitized solar cell element 30b has a metal sheet as the conductive substrate in place of a glass substrate, as in the case of the dye-sensitized solar cell element 30a. Therefore, it is light in weight, thin, and flexible and yet withstands the high-temperature process which leads to improved conversion efficiency and high performance.

The individual layers constituting the dye-sensitized solar cell element 30b may be formed from the same materials and in the same way as in the case of the individual layers constituting the dye-sensitized solar cell element 30a. They may have the same thickness as those of the dye-sensitized solar cell element 30a. The transparent electrode layer 18 may have a thickness no smaller than 0.1 μm and no larger than 5 μm, preferably no smaller than 0.1 μm and no larger than 2 μm.

### Modification of the Second Embodiment

The second embodiment mentioned above may be so modified as to omit the transparent electrode layer 18 shown in FIG. 2E. In this case, the step for treating the porous metal oxide semiconductor layer 16 with TiCl₄ as shown in FIG. 2E may be followed by the step shown in FIG. 2F which is to impregnate the porous metal oxide semiconductor layer 16 with a dye-containing solution, so that the porous metal oxide semiconductor layer 16 supports the dye, and then impregnate the porous metal oxide semiconductor layer 16, the porous insulating layer 14, and the porous carbon layer 12 with the electrolyte solution.

According to the modified process, the porous metal oxide semiconductor layer 16 is impregnated with a dye-containing solution, so that the porous metal oxide semiconductor layer 16 supports the dye. Alternatively, the porous metal oxide semiconductor layer 16 is impregnated with an electrolyte solution, so that the porous metal oxide semiconductor layer 16, the porous insulating layer 14, and the porous carbon layer 12 are impregnated with the electrolyte solution.

According to this modified embodiment similar to the embodiment shown in FIGS. 1A to 1E, the dye-sensitized solar cell element is produced by the steps of coating a metal sheet sequentially with a porous catalyst layer, a porous insulating layer, a porous titanium dioxide layer, and a current collecting grid, allowing the porous titanium dioxide layer to support a dye, impregnating the porous titanium dioxide layer, the porous insulating layer, and the porous catalyst layer with an electrolyte solution, and finally covering the assembly with a transparent plastic resin. The metal sheet functions as a conductive substrate in place of a glass substrate.

Thus the dye-sensitized solar cell element 30 according to the modified embodiment is composed of a working electrode, a counter electrode, and an electrolyte solution as explained below. The working electrode (or the photoelectrode or window electrode) includes the porous metal oxide semiconductor layer 16 and a sensitizing dye supported by particles constituting the porous metal oxide semiconductor layer 16. The counter electrode opposite to the working electrode includes the conductive sheet 10 and the porous carbon layer 12. The electrolyte solution which contains a redox electrolyte is held in the porous metal oxide semiconductor layer 16, the porous insulating layer 14, and the porous carbon layer 12.

The dye-sensitized solar cell element 30 according to the modified embodiment has a metal sheet as the conductive substrate in place of a glass substrate, as in the case of the dye-sensitized solar cell element 30a. Therefore, it is light in weight, thin, and flexible and yet withstands the high-temperature process which leads to improved conversion efficiency and high performance.

The individual layers constituting the dye-sensitized solar cell element according to the modified embodiment may be formed from the same materials and in the same way as in the case of the individual layers constituting the dye-sensitized solar cell element 30a. They may have the same thickness as those of the dye-sensitized solar cell element 30a.

The dye-sensitized solar cell elements according to the first embodiment and the modified second embodiment do not have the transparent electrode layer 18, and this leads to a high conversion efficiency owing to the absence of resistance loss. Moreover, they have the current collecting grid 20 which is composed of conductors arranged at a specific distance and which takes on any of lattice shape, net shape, stripy shape, and comb-like shape. The current-collecting grid 20 is embedded such that at least a portion of it comes into contact with the porous metal oxide semiconductor layer 16. This structure allows the current collecting grid 20 to have a large thickness without the total thickness of the solar cell element increasing. This leads to improvement in current collecting efficiency.

Moreover, the above-mentioned structure reduces the distance between the porous metal oxide semiconductor layer 16 and the porous carbon layer 12 (catalyst layer), and this leads to a higher conversion efficiency. In addition, the conductors of the current collecting grid 20 may be so arranged at adequate intervals as to reduce power loss due to resistance in the porous metal oxide semiconductor layer 16. Therefore, the resulting photoelectric conversion device prevents its conversion efficiency from decreasing due to resistance loss in the porous metal oxide semiconductor layer 16.

### Third Embodiment

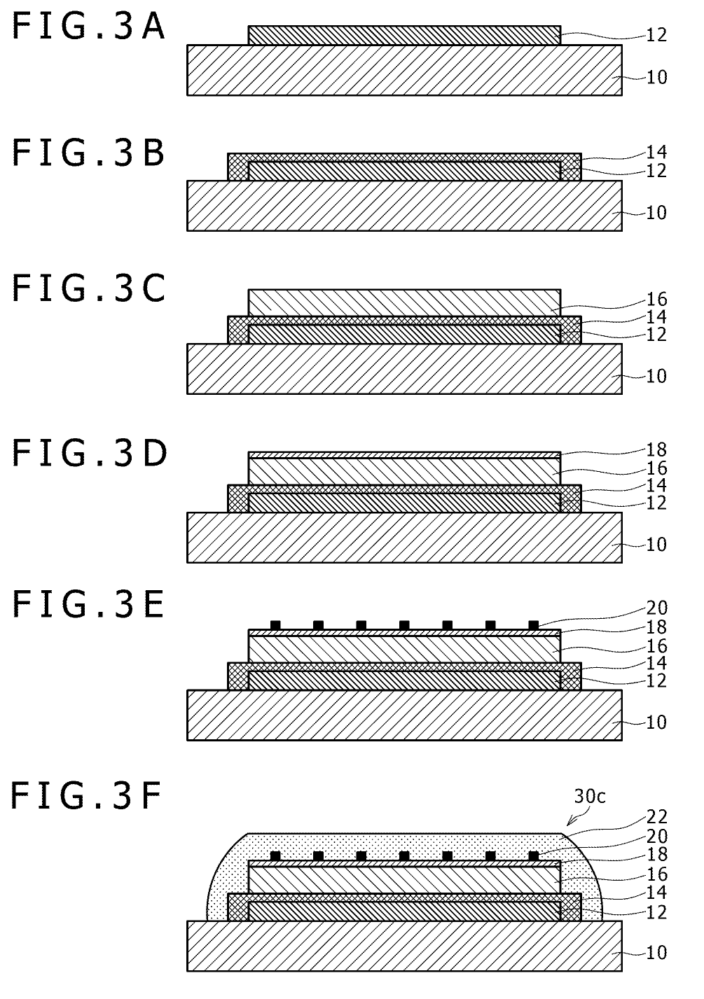

FIGS. 3A to 3F are diagrams illustrating the steps for production of the dye-sensitized solar cell element pertaining to the third embodiment of the present invention.

As shown in FIG. 3F, the dye-sensitized solar cell element 30c is comprised of a substrate and functional layers sequentially formed thereon one over another, as in the case of the dye-sensitized solar cell elements 30a and 30b shown in FIGS. 1A to 1E and 2A to 2F, respectively. The substrate is the conductive sheet 10 of metal, such as Ti, in place of the glass substrate as the counter electrode. The functional layers include the porous carbon layer 12, the porous insulating layer 14, the porous metal oxide semiconductor layer 16, the transparent electrode layer 18, the current collecting grid 20, and the transparent sealing layer 22. The porous metal oxide semiconductor layer 16 contains a dye supported therein. The porous metal oxide semiconductor layer 16, the porous insulating layer 14, and the porous carbon layer 12 are impregnated with an electrolyte solution.

The porous carbon layer 12 is a catalyst layer. The porous insulating layer 14 is formed on the conductive sheet 10 in such a way as to cover the porous carbon layer 12, and the porous insulating layer 14 is covered with the porous metal oxide semiconductor layer 16 formed thereon. The porous metal oxide semiconductor layer 16 is covered with the transparent electrode layer 18, on which the current collecting grid 20 is formed.

As shown in FIGS. 3A to 3F, the dye-sensitized solar cell element 30c is produced in the following way.

The first to third steps proceed as shown in FIGS. 3A, 3B, and 3C in the same way as shown in FIGS. 2A, 2B, and 2C. The conductive sheet 10 of metal such as Ti as a conductive substrate is sequentially coated with the porous carbon layer 12 as a catalyst layer, the porous insulating layer 14, and the porous metal oxide semiconductor layer 16 which is formed from a paste of titanium dioxide (anatase).

The fourth step proceeds as shown in FIG. 3D in the same way as shown in FIG. 2E. The porous metal oxide semiconductor layer 16 is treated with TiCl₄ for improvement in necking among particles of the metal oxide semiconductor, improvement in electron transfer, and improvement in photoelectric conversion efficiency.

The fifth step proceeds as shown in FIG. 3D in the same way as shown in FIG. 2E. The porous metal oxide semiconductor layer 16 is coated with the transparent electrode layer 18.

The sixth step proceeds as shown in FIG. 3E. The transparent electrode layer 18 is provided with the current collecting grid 20 formed thereon. As mentioned above with reference to FIGS. 1A to 1E, the current collecting grid 20 may be formed by any common method such as CVD, sputtering, electroless plating, and printing. Alternatively, it may be a previously formed metal mesh.

The seventh step proceeds as shown in FIG. 3F. The porous metal oxide semiconductor layer 16 is impregnated with a dye-containing solution so that it supports a dye. Subsequently, the porous metal oxide semiconductor layer 16, the porous insulating layer 14, and the porous carbon layer 12 are impregnated with an electrolyte solution.

If the transparent electrode layer 18 is a porous one, it can be impregnated with a dye-containing solution so that the porous metal oxide semiconductor layer 16 supports the dye. The transparent electrode layer 18 can also be impregnated with an electrolyte solution so that the porous metal oxide semiconductor layer 16, the porous insulating layer 14, and the porous carbon layer 12 are impregnated with the electrolyte solution.

If the transparent electrode layer 18 is not a porous one, the porous metal oxide semiconductor layer 16 may be impregnated with a dye-containing solution through a plurality of small through-holes made in the transparent electrode layer 18, so that the porous metal oxide semiconductor layer 16 supports the dye. These small through-holes may also be used to impregnate the porous metal oxide semiconductor layer 16, the porous insulating layer 14, and the porous carbon layer 12 with the electrolyte solution.

Incidentally, the seventh step may be carried out differently than mentioned above by allowing the porous metal oxide semiconductor layer 16 to support the dye, forming the through-holes in the conductive sheet 10, injecting the electrolyte solution through these through-holes, thereby allowing the electrolyte solution to infiltrate into the porous metal oxide semiconductor layer 16, the porous insulating layer 14, and the porous carbon layer 12, and finally sealing the through-holes.

The transparent sealing layer 22 is so formed as to cover at least the transparent electrode layer 18, the porous metal oxide semiconductor layer 16, and the porous insulating layer 14, as shown in FIG. 3F.

According to this embodiment, the dye-sensitized solar cell element 30c is produced in the same way as mentioned above with reference to FIGS. 1A to 1E and 2A to 2F. That is, it is produced by coating the metal sheet as the conductive substrate in place of a glass substrate sequentially with the porous catalyst layer, the porous insulating layer, the porous titanium dioxide layer, the transparent electrode layer, and the current collecting grid, and subsequently allowing the porous titanium dioxide layer to support the dye and impregnating the porous titanium dioxide layer, the porous insulating layer, and the porous catalyst layer with the electrolyte solution, and finally coating the entire assembly with the transparent plastic resin.

Thus the dye-sensitized solar cell element 30c is composed of a working electrode, a counter electrode, and an electrolyte solution as explained below. The working electrode (or the photoelectrode or window electrode) includes the porous metal oxide semiconductor layer 16 and a sensitizing dye supported by particles constituting the porous metal oxide semiconductor layer 16. The counter electrode opposite to the working electrode includes the conductive sheet 10 and the porous carbon layer 12. The electrolyte solution which contains a redox electrolyte is held in the porous metal oxide semiconductor layer 16, the porous insulating layer 14, and the porous carbon layer 12.

The dye-sensitized solar cell element 30c has a metal sheet as the conductive substrate in place of a glass substrate, as in the case of the dye-sensitized solar cell elements 30a and 30b. Therefore, it is light in weight, thin, and flexible and yet withstands the high-temperature process which leads to improved conversion efficiency and high performance.

The individual layers constituting the dye-sensitized solar cell element 30c according to this embodiment may be formed from the same materials and in the same way as in the case of the individual layers constituting the dye-sensitized solar cell element 30a or 30b. They may have the same thickness as those of the dye-sensitized solar cell element 30a or 30b.

Incidentally, the dye-sensitized solar cell elements 30a, 30b, and 30c according to the first to third embodiments may employ the conductive sheet 10 made of conductive porous sheet such as carbon paper or titanium foam sheet used for fuel cells.

In the case where the conductive sheet 10 is a conductive porous sheet, the steps shown in FIGS. 1F, 2F, and 3F, which permit the porous metal oxide semiconductor 16 to support the dye and also permit the porous metal oxide semiconductor layer 16 to be impregnated with the electrolyte solution, may be carried out through the porous conductive sheet 10 without forming the through-holes in the porous conductive sheet 10.

According to this embodiment, the dye-containing solution is infiltrated into the porous metal oxide semiconductor layer 16 through the porous conductive sheet 10, the porous carbon layer 12, and the porous insulating layer 14. This process permits the porous metal oxide semiconductor layer 16 to support the dye. Then, the electrolyte solution is infiltrated into the porous metal oxide semiconductor layer 16 through the porous conductive sheet 10, the porous carbon layer 12, and the porous insulating layer 14.

In the case where the conductive sheet 10 is a conductive porous sheet, the transparent sealing layer 22 (shown in FIGS. 1A to 3F) is formed in such a way that it encloses the conductive sheet 10. According to an alternative process, the conductive sheet 10 may be fixed onto another substrate (film) and then it is covered with the sealing resin.

The dye-sensitized solar cell elements 30a, 30b, and 30c according to the first to third embodiments mentioned above work in such a way that a load is connected to the positive terminal (which is a conductor (not shown in FIGS. 1A to 3F) connected to the current collecting grid 20 and attached to the outside of the transparent sealing layer 22) and the negative terminal (which is that region of the conductive sheet 10 which exposes itself from the outside of the transparent sealing layer 22).

### Fourth Embodiment

This embodiment is intended to integrate on a single substrate a number of dye-sensitized solar cell elements mentioned in the first to third embodiments.

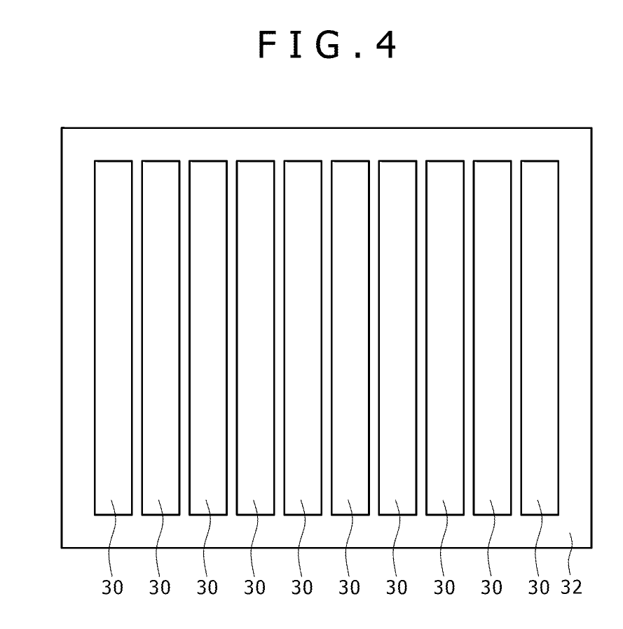

FIG. 4 is a sectional view showing the dye-sensitized solar cells in integrated form pertaining to the fourth embodiment of the present invention.

According to this embodiment, a number of dye-sensitized solar cell elements each described in the first to third embodiments are integrated on the insulating substrate 32 as shown in FIG. 4. The substrate 32 having a large area is provided with several pieces of the conductive sheet 10 by adhesion or with several pieces of conductive layers (each functioning as the conductive sheet 10). Each of the conductive sheets 10 is processed to form the dye-sensitized solar cell element as shown in FIGS. 1A to 3F.

Each of the dye-sensitized solar cell elements 30 (30a, 30b, and 30c) prepared as mentioned above has a positive terminal which is a conductor (not shown in FIGS. 1A to 4) connected to the current collecting grid 20 as a constituent of the dye-sensitized solar cell element and attached to the outside of the transparent sealing layer 22, and also has a negative terminal (not shown in FIGS. 1A to 4) which is that region of the conductive sheet 10 which exposes itself from the outside of the transparent sealing layer 22. When the dye-sensitized solar cell element 30 (30a, 30b, and 30c) is in use, a load is connected in series across the positive and negative terminals.

The conductive sheet 10 (as the substrate 32) of large area may be provided with several pieces of the dye-sensitized solar cell elements shown in FIGS. 1A to 3F which are formed at one time. In this case, a portion of the conductive sheet 10 is made to function as the negative terminal, and the negative terminal is connected to a positive terminal commonly connected to the current collecting grids 20 as constituents of the dye-sensitized solar cell elements, such that several pieces of the dye-sensitized solar cell elements are arranged in parallel.

### Fifth Embodiment

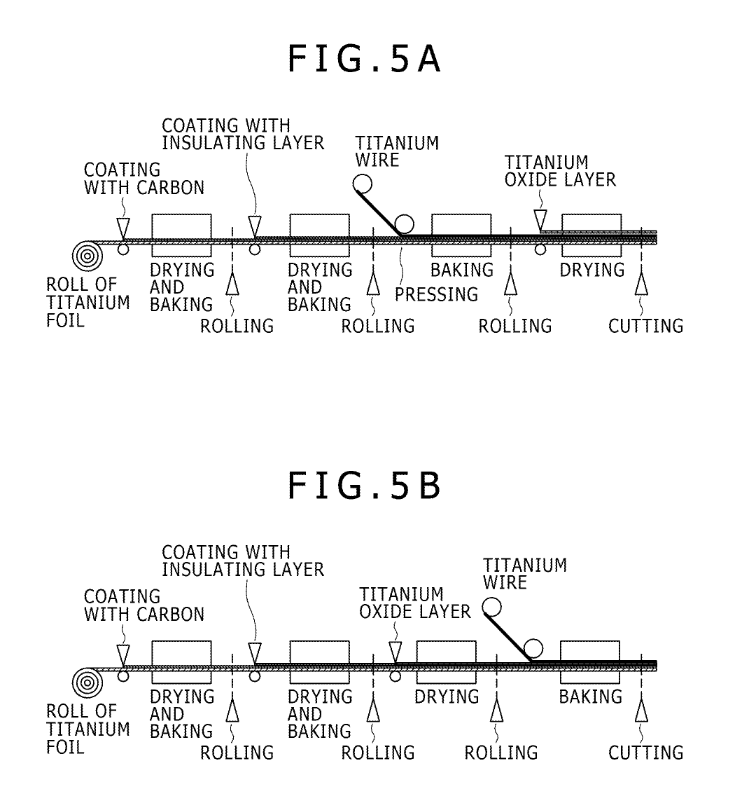

FIGS. 5A and 5B are diagrams illustrating the steps for production of the dye-sensitized solar cell by the roll-to-roll process pertaining to one embodiment of the present invention.

The dye-sensitized solar cell element shown in FIGS. 1A to 3F can be produced by the roll-to-roll process shown in FIGS. 5A and 5B. This process employs a roll of titanium foil.

The roll-to-roll process shown in FIG. 5A includes the steps shown in FIGS. 1A to 1D. The roll-to-roll process shown in FIG. 5B includes the steps shown in FIGS. 2A to 2D.

As shown in FIG. 5A, the roll-to-roll process starts with coating a titanium foil with a carbon-containing paste, followed by drying and baking, so that the porous carbon layer 12 is formed. In the next step, the porous carbon layer 12 is coated with a paste, followed by drying and baking, so that the porous insulating layer 14 is formed. Next, the porous insulating layer 14 is provided with the current collecting grid 20 having titanium wires composed of a plurality of columns or which is a titanium mesh sheet. The porous insulating layer 14 is coated further with a paste containing titanium dioxide in such a way as to cover the current collecting grid 20, followed by drying and baking. Thus there is formed the porous metal oxide semiconductor layer 16.

As shown in FIG. 5B, the roll-to-roll process starts with coating a titanium foil with a carbon-containing paste, followed by drying and baking, so that the porous carbon layer 12 is formed. In the next step, the porous carbon layer 12 is coated with a paste, followed by drying and baking, so that the porous insulating layer 14 is formed. Next, the porous insulating layer 14 is coated with a paste containing titanium dioxide, followed by drying and baking. Thus there is formed the porous metal oxide semiconductor layer 16. The porous metal oxide semiconductor layer 16 has its surface grooved (not shown) and the resulting grooves are given titanium wires composed of a plurality of columns or a titanium mesh sheet which functions as the current collecting grid 20.

The processes shown in FIGS. 5A and 5B ends with cutting the layered sheet into small pieces. The small pieces in groups undergo the above-mentioned finishing steps (not shown) for treatment of the porous metal oxide semiconductor layer 16 with TiCl₄, incorporation of the porous metal oxide semiconductor layer 16 with a dye, impregnation of the porous metal oxide semiconductor layer 16, the porous insulating layer 14, and the porous carbon layer 12 with an electrolyte solution, and formation of the transparent sealing layer 22.

According to the existing process, the porous metal oxide semiconductor layer 16 is formed by coating a substrate with a paste of titanium dioxide, followed by drying and baking at 400° C. to 500° C. The coating process involves baking at high temperatures and the subsequent treatment with TiCl₄ also involves baking at high temperature. Therefore, the existing process presents difficulties in producing dye-sensitized solar cell elements by using a plastics film as the substrate.

The process of the present invention differs from the existing one in that the substrate is the conductive sheet (metal sheet) 10 which has an adequate thickness for the conductive sheet to be flexible. This substrate withstands baking at high temperatures and hence permits the porous metal oxide semiconductor layer 16 to be formed by the roll-to-roll process which needs baking at high temperatures. Thus, the process of the present invention permits the dye-sensitized solar cell elements to be produced partly by continuous steps including the step of forming the porous metal oxide semiconductor layer 16. This contributes to high productivity.

The present invention has been described above with reference to its preferred embodiments, which are not intended to restrict the scope thereof but which may be variously modified within the technical idea thereof.

The present invention provides a photoelectric conversion device which is light in weight, thin, and flexible, and which has a high conversion efficiency. The present invention also provides a process for producing said photoelectric conversion device.

The present application contains subject matter related to that disclosed in Japanese Priority Patent Application JP 2010-080221 filed in the Japan Patent Office on Mar. 31, 2010, the entire content of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A process for producing a photoelectric conversion device, comprising:
a first step of coating a surface of a conductive substrate with a porous catalyst layer;
a second step of coating the surface of said conductive substrate with a porous insulating layer in such a way as to cover said porous catalyst layer;
a third step of coating the surface of said porous insulating layer with a current collecting layer;
a fourth step of coating the surface of said porous insulating layer with a porous metal oxide semiconductor layer in such a way as to cover said current collecting layer;
a fifth step of allowing said porous metal oxide semiconductor layer to support a dye;
a sixth step of impregnating said porous metal oxide semiconductor layer, said porous insulating layer, and said porous catalyst layer with an electrolyte solution; and
a seventh step of forming a transparent sealing layer in such a way as to cover at least said porous insulating layer and said porous metal oxide semiconductor layer.

2. The process for producing a photoelectric conversion device as defined in claim 1, wherein said sixth step includes a substep of making an opening that penetrates said conductive substrate, a substep of injecting said electrolyte solution through said opening, thereby impregnating said porous metal oxide semiconductor layer, said porous insulating layer, and said porous catalyst layer with said electrolyte solution, and a substep of sealing said opening.

3. A photoelectric conversion device comprising:
a porous catalyst layer which is formed on a surface of a conductive substrate;
a porous insulating layer which is formed on the surface of said conductive substrate in such a way as to cover said porous catalyst layer;
a current collecting layer which is formed on the surface of said porous insulating layer;
a porous metal oxide semiconductor layer which is formed on the surface of said porous insulating layer in such a way as to cover said current collecting layer; and
a transparent sealing layer which is formed on the surface of said conductive substrate in such a way as to cover at least said porous insulating layer and said porous metal oxide semiconductor layer;
wherein said porous metal oxide semiconductor layer supports a dye and said porous metal oxide semiconductor layer, said porous insulating layer, and said porous catalyst layer contain an electrolyte solution.

4. A process for producing a photoelectric conversion device, comprising:
a first step of coating a surface of a conductive substrate with a porous catalyst layer;
a second step of coating the surface of said conductive substrate with a porous insulating layer in such a way as to cover said porous catalyst layer;
a third step of coating the surface of said porous insulating layer with a porous metal oxide semiconductor layer;
a fourth step of forming a current collecting layer in such a way that it is at least partly embedded in said porous metal oxide semiconductor layer;
a fifth step of forming a transparent electrode layer in such a way that it comes into contact with said porous metal oxide semiconductor layer and said current collecting layer;
a sixth step of allowing said porous metal oxide semiconductor layer to support a dye;
a seventh step of impregnating said porous metal oxide semiconductor layer, said porous insulating layer, and said porous catalyst layer with an electrolyte solution; and
an eighth step of forming a transparent sealing layer in such a way as to cover at least said porous insulating layer, said porous metal oxide semiconductor layer, and said transparent electrode layer.

5. The process for producing a photoelectric conversion device as defined in claim 4, wherein said sixth step includes a substep of making an opening that penetrates said conductive substrate, a substep of injecting said electrolyte solution through said opening, thereby impregnating said porous metal oxide semiconductor layer, said porous insulating layer, and said porous catalyst layer with said electrolyte solution, and a substep of sealing said opening.

6. A photoelectric conversion device comprising:
a porous catalyst layer which is formed on a surface of a conductive substrate;
a porous insulating layer which is formed on the surface of said conductive substrate in such a way as to cover said porous catalyst layer;
a porous metal oxide semiconductor layer which is formed on the surface of said porous insulating layer;
a current collecting layer which is formed in such a way that it is at least partly embedded in said porous metal oxide semiconductor layer;
a transparent electrode layer which is formed in such a way that it comes into contact with said porous metal oxide semiconductor layer and said current collecting layer; and
a transparent sealing layer which is so formed as to cover at least said porous insulating layer, said porous metal oxide semiconductor layer, and said transparent electrode layer;
wherein said porous metal oxide semiconductor layer supports a dye and said porous metal oxide semiconductor layer, said porous insulating layer, and said porous catalyst layer contain an electrolyte solution.

7. A process for producing a photoelectric conversion device, comprising:
a first step of coating a surface of a conductive substrate with a porous catalyst layer;
a second step of coating the surface of said conductive substrate with a porous insulating layer in such a way as to cover said porous catalyst layer;
a third step of coating the surface of said porous insulating layer with a porous metal oxide semiconductor layer;
a fourth step of forming a transparent electrode layer on the surface of said porous metal oxide semiconductor layer;
a fifth step of forming a current collecting layer which is formed on the surface of said transparent electrode layer;
a sixth step of allowing said porous metal oxide semiconductor layer to support a dye;
a seventh step of impregnating said porous metal oxide semiconductor layer, said porous insulating layer, and said porous catalyst layer with an electrolyte solution; and
an eighth step of forming a transparent sealing layer in such a way as to cover at least said porous insulating layer, said porous metal oxide semiconductor layer, and said transparent electrode layer.

8. The process for producing a photoelectric conversion device as defined in claim 7, wherein said seventh step includes a substep of making an opening that penetrates said conductive substrate, a substep of injecting said electrolyte solution through said opening, thereby impregnating said porous metal oxide semiconductor layer, said porous insulating layer, and said porous catalyst layer with said electrolyte solution, and a substep of sealing said opening.

9. A photoelectric conversion device comprising:
a porous catalyst layer which is formed on a surface of a conductive substrate;
a porous insulating layer which is formed on the surface of said conductive substrate in such a way as to cover said porous catalyst layer;
a porous metal oxide semiconductor layer which is formed on the surface of said porous insulating layer;
a transparent electrode layer which is formed on the surface of said porous metal oxide semiconductor layer;
a current collecting layer which is formed on the surface of said transparent electrode layer; and
a transparent sealing layer which is so formed as to cover at least said porous insulating layer, said porous metal oxide semiconductor layer, and said transparent electrode layer;
wherein said porous metal oxide semiconductor layer supports a dye and said porous metal oxide semiconductor layer, said porous insulating layer, and said porous catalyst layer contain an electrolyte solution.
